(19) United States
(12) Patent Application Publication
(10) Pub. No.: US 2025/0276488 A1
(43) Pub. Date: Sep. 4, 2025

(54) A DEVICE FOR PRODUCING FIBER-REINFORCED COMPOSITES USING PHOTOPOLYMER RESIN AND A METHOD FOR PRODUCING FIBER-REINFORCED COMPOSITES USING PHOTOPOLYMER RESIN

(71) Applicant: KARADENIZ TEKNIK UNIVERSITESI TEKNOLOJI TRANSFERI UYGULAMA VE ARASTIRMA MERKEZI MÜDÜRLÜGÜ, Trabzon (TR)

(72) Inventors: Kutay ÇAVA, Trabzon (TR); Hamdullah ÇUVALCI, Trabzon (TR); Mustafa ASLAN, Trabzon (TR); Hüseyin IPEK, Trabzon (TR); Altug USUN, Trabzon (TR)

(73) Assignee: KARADENIZ TEKNIK UNIVERSITESI TEKNOLOJI TRANSFERI UYGULAMA VE ARASTIRMA MERKEZI MÜDÜRLÜGÜ, Trabzon (TR)

(21) Appl. No.: 18/860,552

(22) PCT Filed: Aug. 3, 2023
(86) PCT No.: PCT/TR2023/050768

§ 371 Date: Oct. 25, 2024

(30) Foreign Application Priority Data
Dec. 7, 2022 (TR) 2022/018781

(51) Int. Cl. B29C 64/165; B29C 64/176; B29C 64/282; B29C 64/321; B33Y 10/00; B33Y 30/00; B33Y 40/00

(52) U.S. Cl. CPC B29C 64/165; B29C 64/176; B29C 64/282; B29C 64/321; B33Y 10/00; B33Y 30/00; B33Y 40/00

(57) ABSTRACT

The invention relates to a device and a production method enabling the rapid production of fiber-reinforced composites using photopolymer resin through additive manufacturing, such as Direct Light Processing (DLP), Stereolithography (SLA), or similar methods, as compared to conventional production methods.

### TECHNICAL FIELD

The invention relates to a device and a production method enabling the rapid production of fiber-reinforced composites using photopolymer resin through additive manufacturing, such as Direct Light Processing (DLP), Stereolithography (SLA), or similar methods, as compared to conventional production methods.

### BACKGROUND

For many years, the use of prepreg production technology and various geometries of plates has been prevalent in the aerospace, space, and automotive industries. Prepreg plates have become indispensable in these sectors due to their significantly high strength and low relative densities. In the prepreg production method, techniques such as hand lay-up or automated fiber placement are employed. Subsequently, the obtained parts are usually placed in an autoclave environment, and a vacuum is applied to minimize any possible voids within the part. This process ensures a more uniform and high-quality composite material. Indeed, the prepreg production process can be time-consuming, taking hours or even days, depending on the complexity of the part. Additionally, it requires the use of molds during the application. Mold production adds extra time and cost to the process and becomes unusable after a certain amount of production.

Additive manufacturing methods are preferred in various applications to eliminate the use of molds. However, the mechanical properties of thermoplastic materials produced with additive manufacturing are significantly lower compared to fiber-resin composite parts produced as pre-pregs. In order to address this issue, studies have been conducted in both literature and industry, and various types of fibers have been introduced into thermoplastic materials. Fiber-reinforced composite manufacturing has been increasingly adopted over the past five years, leading to a growing trend and expanded applications in different industries. Markforged company can be regarded as a pioneer of this technology. They have made it possible to produce parts with aluminum strength using a 3D printer that can be placed in homes. (https://markforged.com/3d-printers/mark-two). It is indeed possible to come across a wide variety of studies in the literature and industrial applications related to this method. However, all the mentioned studies have been conducted using a fused deposition modelling (FDM) device that utilizes thermoplastic resin.

In industrial applications, there has been no reported study on the manufacturing of fiber-reinforced composites using photopolymer resin printers such as DLP (Digital Light Processing) or SLA (Stereolithography). However, in the literature, there have been studies on DLP printers incorporating fiber, carbon nanotubes, various metal powders, and other particulate additives in the manufacturing process.

While no similar method has been found in photopolymer additive manufacturing techniques, there is a patent application numbered U.S. Pat. No. 3,865,589 related to production using photopolymer. This patent demonstrates the joining of only one layer of mesh or fabric with another part by using ultraviolet light for support. However, in both literature and industrial applications, no printer, method, apparatus, or device has been encountered that utilizes photopolymer resins as the main material, incorporating continuous fiber or fabric reinforcement for additive manufacturing of fiber-reinforced composites.

### BRIEF DESCRIPTION OF THE INVENTION

The invention pertains to a device that enables the production of fiber-reinforced composites much faster compared to conventional production methods in additive manufacturing using direct light processing (DLP), stereolithography (SLA), and similar techniques involving photopolymer production. With this device, not only can fast production be achieved without compromising mechanical properties, but it also allows for the use of various materials in different application areas, in addition to photopolymer. As a result, the produced materials can be endowed with desired mechanical, thermal, magnetic, medical, and other properties as needed.

### LIST OF FIGURES

FIG. 1. Fiber roll zone, cutting zone and printing zone

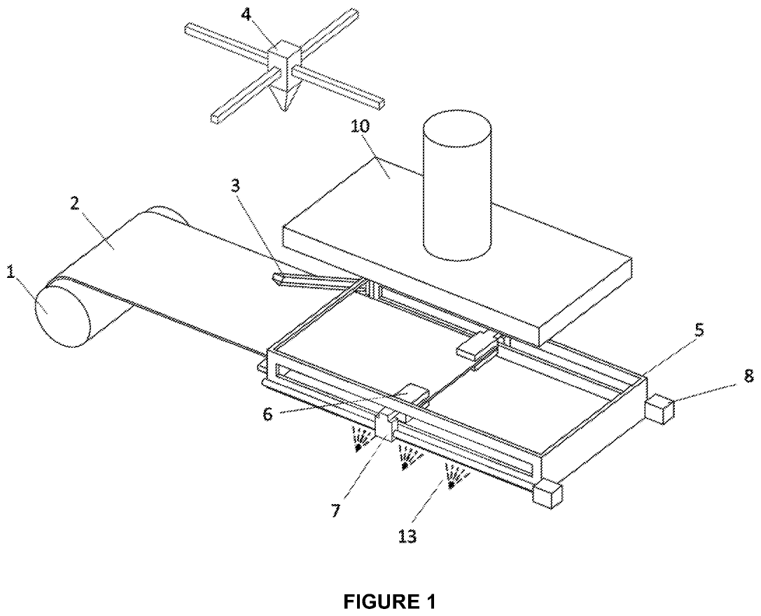

FIG. 2. Interchangeable print bed, printing zone and interchangeable print reservoir zones

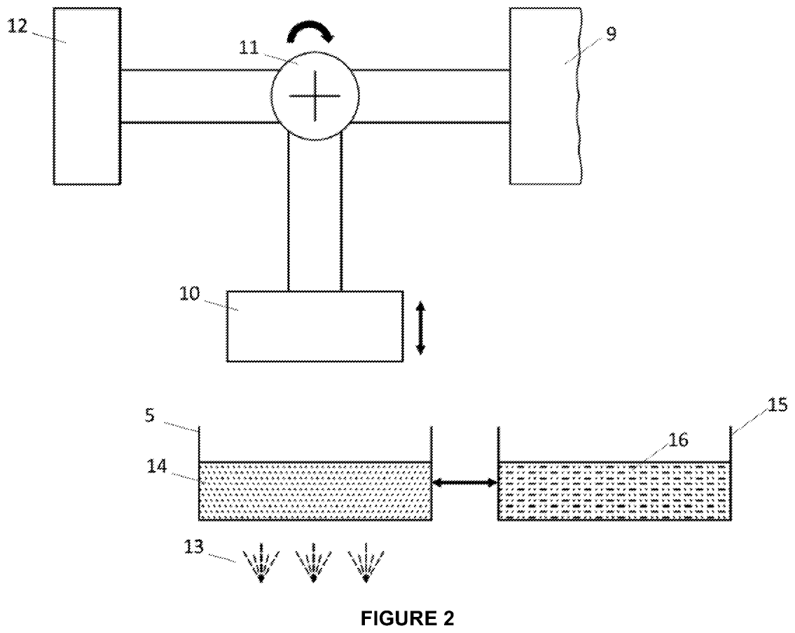

FIG. 3. Prepreg-like alternative manufacturing method.

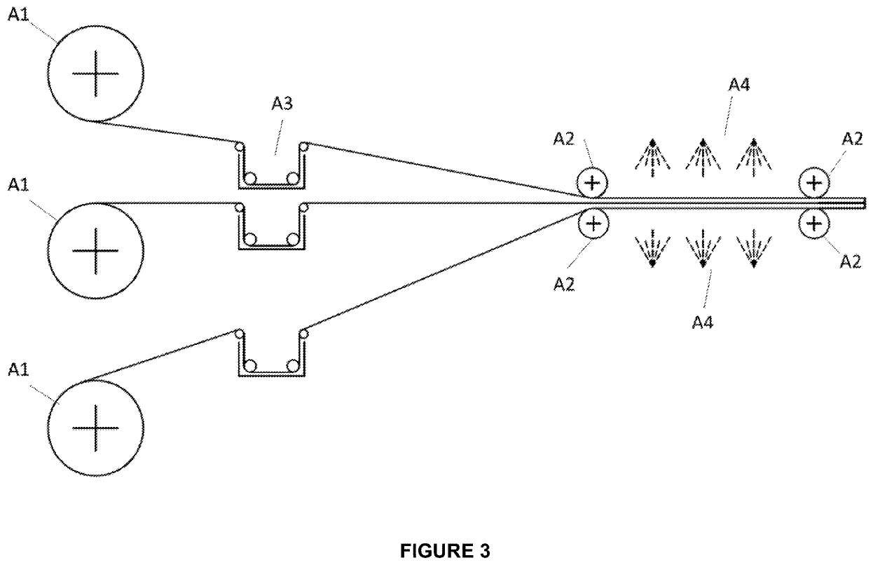

### REFERENCES IN THE FIGURES

1. Fiber roll
2. Fiber
3. Linear cutter
4. Alternative two axis cutter
5. Composite printing zone
6. Fiber holder
7. Fiber holding motor
8. Fiber pulling motor
9. Impregnated board
10. Printing board
11. Printing and impregnated board changing apparatus
12. Additional printing boards
13. UV light source
14. Photopolymer resin
15. Different Resin Reservoir
16. Resin with/without Additives
A1. Fiber Roll
A2. Guide Rollers
A3. Photopolymer Resin Bath
A4. UV Photopolymer Curing Zone

### DETAILED DESCRIPTION OF THE INVENTION

The invention relates to a device and a production method that enables the much faster production of fiber-reinforced composites compared to conventional production methods, using additive photopolymer manufacturing techniques, such as direct light processing (DLP), stereolithography (SLA), and similar methods. With the mentioned device, it becomes possible to produce fiber-reinforced composites using various resins and fiber reinforcements, such as carbon, glass, Kevlar, etc., for the first time in SLA, DLP, and similar printers that utilize photopolymer resin (14).

Technical effects of the invention are;
Thanks to the rapid curing time of the photopolymer resin (14), the production speed is reduced from hours compared to conventional production methods to minutes and even seconds under suitable conditions.
The additive manufacturing method allows the production of complex geometries (such as sandwich structures, honeycomb, exotic geometries, TPMS geometry, BCC geometry, etc.) with porous production in the central part of the system, while also possessing mechanical properties close to those achieved by the prepreg manufacturing method.
The method enables the imparting of mechanical, thermal, magnetic, and medical properties to the produced part by using various types of resins.
Similarly, this method allows production with the desired fiber reinforcement.

With our invention, it is possible to manufacture versatile parts that can be used in various applications using different resins with flexible, rigid, biocompatible, electrically conductive, thermally conductive, thermally insulating, or many other different physical and/or chemical properties.

The invention is a device based on additive manufacturing technology, which uses photopolymer resin (14) to achieve the high-speed production of plate or complex-geometry composite parts. With this method, the production of plates, depending on their thickness, can be achieved within 5-30 minutes, whereas standard composite production may take hours. This remarkable reduction in production time is primarily due to the rapid penetration of the photopolymer resin (14) into the fibers (2) and its ability to cure under UV light within seconds.

Production in the device begins with the placement of a fiber roll (1), which supplies fibers (2), into the device. The fiber roll (1) can comprise any type of fiber (2) such as glass, carbon, Kevlar, etc. For directing these fibers (2), a holding and pulling system is utilized, comprising a fiber holder (6) and a fiber holding motor (7). In another embodiment of the invention, this pulling system can also be placed on a linear cutter (3) or an alternative two-axis cutter (4). In another embodiment of the invention, a production belt can be used in this area for directing the fibers (2). Once directed into a composite printing zone (5), the fibers (2) need to be cut. In this zone, the cutting of the fibers (2) in a straight manner is achieved using a linear cutter (3). For this purpose, a mechanism such as a cutting tool, burning tool, drilling tool, etc., can be placed on a linear slide. Alternatively, different types of cutters like scissors, guillotine, or other cutting tools can also be used. Additionally, by using an alternative two-axis cutter (4), it is possible to produce complex-geometry parts instead of just plates. For directing the fibers (2) into the composite printing zone (5), a controlled fiber holder (6) is utilized, operated by a fiber holding motor (7). The fiber holding motor (7) will be active while the fiber holder (6) compresses the fibers (2), and at the same time, a fiber pulling motor (8) will be engaged. When the fiber (2) reaches the desired position, the fiber holder (6) will release the fiber (2) under the control of the fiber holding motor (7).

The fibers (2) that have entered the resin are rapidly wetted by the photopolymer resin (14). However, to accelerate and/or homogenize this wetting process, an impregnation board (9) is used. The impregnation board (9), whether modified with a serrated surface or flat, improves the placement of the photopolymer resin (14) between the fibers (2). After the impregnation process is completed, the fibers (2) and photopolymer resin (14) are ready for printing. In this case, the printing and impregnation board exchange apparatus (11) aligns the printing board (10) with the printing zone (5) by changing the positions of the boards using a rotating or sliding mechanism. The printing board (10) is directed downward and enters the photopolymer resin (14). Furthermore, in another embodiment of the invention, a heater placed within the printing board (10) can be used to heat the resin (14) to the desired temperature, thereby altering its viscosity. Heated resin (14) can impregnate the fibers (2) more effectively. Here, with the help of a force sensor or mechanical calculations based on the strain resulting from the distance, a specific force is applied to the fiber (2) surface by the printing board (10). Subsequently, ultraviolet light sources (13) are used to cure the photopolymer resin (14). As a result, the printing of a layer is completed. By using additional printing boards (12), it is possible to change the printing board (10) during or after the printing process. This allows multiple printings to be carried out simultaneously or enables the continuation of printing a second part without waiting for the removal of the printed part from the board after completion. Finally, in this system, the printing zone (5) is also adjustable. This allows the composite printing zone (5) to be changed according to the different resin pools (15) during the printing process. Consequently, different resins (16) or fiber (2) types can be used in each layer of the printing. In this system, different types and compositions of resin can be applied in each layer or between different zones of the composite structure. For example, rigid photopolymer can be used on the surface, while a flexible photopolymer resin can be applied internally, or vice versa. Ceramic (ZnO, Fe₂O₃, and/or Fe, B, Ag, Ni, etc.) metallic nano and micro powders placed in the pools can be produced separately or together as hybrids in different layers with fiber-reinforced resins, allowing the production of multi-layered components with different components according to preferences.

In another embodiment of the invention, to enable wider and continuous production using photopolymer resin (14), different types of fibers (2) can be used as the fiber roll (1) within the same plate, and adjustable fiber rolls (A1) can be employed based on the desired composite plate thickness to be achieved at the end of the production process. The number of the mentioned fiber rolls (A1) is at least one. To allow the fibers (2) to take the shape of the plate and move smoothly within the system, guide rollers (A2) have been used. The guide rollers (A2) can be freely rotating to increase production speed or fixed to ensure the tension of the fibers (2), which is crucial for proper impregnation of the photopolymer resin (14) into the fibers (2). After the fibers (2) exit the fiber rolls (A1), additive or additive-free photopolymer resin baths (A3) have been provided to wet their surfaces with photopolymer resin (14). Here, various pure photopolymers can be used, and in addition, various additives can be mixed in to impart different mechanical, thermal, magnetic, or medical properties to the desired parts. After passing through the photopolymer resin bath (A3), the fibers (2) are cured in the UV photopolymer curing zone (A4) using UV light sources. Depending on the thickness of the part, these light sources can be unidirectional or bidirectional. When curing the entire plate is challenging due to the fiber (2) and additives, multiple guide rollers (A2) and UV photopolymer curing zones (A4) can be placed. This allows for step-by-step production, enabling the increase of plate thickness.

A production method subject to invention comprises the following steps:
Selection of fibers (2) from different types and with different properties suitable for the physical or chemical characteristics of the desired part and placing them onto a fiber roll (1),
Directing the fibers (2) to the printing table (10) and cutting them according to the desired shape,
Optionally, using an impregnation table (9), aligning the printing table (10), and applying force on the fibers (2),
Performing curing with a UV light source (13),
Changing the composite printing zone (5) to print simultaneously during printing or to use different polymers in different layers,
Completing the layered production by repeating these processes,
Using additional printing tables to continue with another printing without the need to clean the table after the printing is finished.

1. A device for producing fiber-reinforced composites using photopolymer resin comprising:
fiber roll supplying fibers into the device for producing fiber-reinforced composites using photopolymer resin;
a holding and pulling system further comprising a fiber holder and a fiber holding motor for directing the fibers;
a composite printing zone;
a fiber pulling motor being activated while the fiber holding motor providing a fiber holder to compress the fibers for directing the fiber into the composite printing zone and releasing it when it reaches;
a linear cutter for cutting the fibers-directed into the composite printing zone straight;
an impregnation board for wetting the fibers, that have entered the resin, rapidly by a photopolymer resin;
a printing boards;
a printing and impregnation board exchange apparatus for aligning the printing board with the composite printing zone; and
UV light sources.

2. The device for producing fiber-reinforced composites using photopolymer resin according to claim 1 comprising a holding system further comprising a fiber holder and a fiber holding motor, which is placed on the linear cutter or an alternative two-axis cutter.

3. The device for producing fiber-reinforced composites using photopolymer resin according to claim 1 comprising a production belt for directing the fibers placed into the device for producing fiber-reinforced composites using photopolymer resin.

4. The device for producing fiber-reinforced composites using photopolymer resin according to claim 1 comprising the alternative two-axis cutter to produce parts with complex-geometry instead of plates.

5. The device for producing fiber-reinforced composites using photopolymer resin according to claim 1 comprising additional printing boards to change the printing board during or after the printing process and to allow multiple printings to be carried out simultaneously or enables the continuation of printing a second part without waiting for the removal of the printed part from the board after completion.

6. The device for producing fiber-reinforced composites using photopolymer resin according to claim 1 comprising the composite printing zone which has a changeable structure according to the different resin pools.

7. The device for producing fiber-reinforced composites using photopolymer resin according to claim 1 comprising the fiber roll which is at least a fiber roll that can be changed based on the desired composite plate thickness to be achieved at the end of the production process or based on usage of different types of fibers within the same plate.

8. The device for producing fiber-reinforced composites using photopolymer resin according to claim 7 comprising guide rollers to allow the fibers to take the shape of the plate and move smoothly within the system.

9. The device for producing fiber-reinforced composites using photopolymer resin according to claim 8 comprising the guide rollers can rotate freely or fixed.

10. The device for producing fiber-reinforced composites using photopolymer resin according to claim 7 comprising photopolymer resin baths to wet the fibers with photopolymer resin after they exit the fiber rolls.

11. The device for producing fiber-reinforced composites using photopolymer resin according to claim 10 comprising a UV photopolymer curing zone to cure the fibers using UV light sources after they pass through the photopolymer resin bath.

12. The device for producing fiber-reinforced composites using photopolymer resin according to claim 1 comprising a heater within the printing board to heat the resin to the desired temperature thereby alter its viscosity.

13. The device for producing fiber-reinforced composites using photopolymer resin according to claim 1 comprising a force sensor to calculate the force applied to the fiber surface by the printing board.

14. A method for producing fiber-reinforced composites using photopolymer resin comprising:
selecting fibers from different types and with different properties suitable for the physical or chemical characteristics of the desired part and placing them onto a fiber roll;
directing the fibers to the printing table and cutting them according to the desired shape;
optionally, using an impregnation table, aligning the printing table, and applying force on the fibers;
performing curing with a UV light source;
changing the composite printing zone to print simultaneously during printing or to use different polymers in different layers;
completing the layered production by repeating these processes; and
using additional printing tables to continue with another printing without the need to clean the table after the printing is finished.
